(19) United States
(12) Patent Application Publication
(10) Pub. No.: US 2006/0145763 A1
(43) Pub. Date: Jul. 6, 2006

(54) Low voltage class ab transconductor circuits

(75) Inventor: John B. Hughes, Hove (GB)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: Koninklijke Philips Electronics N.V., BA Eindhoven (NL)

(21) Appl. No.: 10/545,473

(22) PCT Filed: Jan. 30, 2004
(86) PCT No.: PCT/IB04/00307

§ 371 Date: Aug. 12, 2005

(30) Foreign Application Priority Data
Feb. 13, 2003 (GB) 0303248.9

(51) Int. Cl. H03F 3/18

(52) U.S. Cl. 330/264

(57) ABSTRACT

A class AB transconductor circuit comprises complementary PMOS and NMOS transistors (10, 12) having their source-drain paths connected in series between first and second voltage supply rails (14, 16). An output terminal (20) is coupled to a junction of said series connected source-drain paths. Gate electrodes of the PMOS and NMOS transistors are coupled to an input terminal (18) by way of respective first and second paths each of which includes first and second bias voltage supply sources (32, 34). The quiescent gate voltages of the PMOS and NMOS are offset from the quiescent input voltage by the equal and opposite voltages (V_{b}) of the first and second bias voltage supply sources thereby reducing the apparent threshold voltage (Vₜ′) of the PMOS and NMOS transistors by the value of the bias voltage supply sources. Balanced class AB transconductor circuits are also disclosed.

The present invention relates to low voltage class AB transconductor circuits having application in gyrator channel filters for low power wireless transceivers/receivers which may be fabricated as integrated circuits.

Class AB transconductors fabricated using integrated CMOS transistors have been successfully used in gyrator channel filters for modern low power wireless transceivers/receivers having application in Bluetooth and Zigbee. In order to operate optimally, the CMOS transistors require a supply voltage of about four times the CMOS gate threshold voltage. This criterion is becoming difficult to achieve in newer sub-micron integrating processes because leakage in the logic gates is necessitating higher gate threshold voltages which at least in theory require higher supply voltages if the criterion is to be followed.

U.S. Pat. No. 6,031,423 discloses a rail-to-rail op amp (operational amplifier) which includes a N-channel input stage and a P-channel input stage for receiving respectively an inverting input and a non-inverting input. The N-channel input stage comprises a set of N-channel MOS transistors and the P-channel input stage comprises a set of P-channel MOS transistors. When operating in a differential mode as one input voltage increases the other input voltage decreases so that there is no damaging substrate current. However when operating in a common mode in which both signal voltages are increasing and the transistors of the P-channel input stage are turning-off, damaging substrate current occurs. In order to protect the transistors of the P-channel input stage the threshold voltage is reduced by creating a negative bulk-source voltage, for example by subtracting the source voltage from the bulk voltage, causing a reduction in the damaging current flowing through the substrate when the current through the P-channel input stage decreases. By protecting the transistors of the P-channel input stage it is possible to achieve rail-to-rail operation at a reduced supply current while minimizing damaging current through the substrate. This method of protecting a P-channel transistor is known in the art as changing the back gate voltage on the N-well of the transistor. U.S. Pat. No. 6,031,423 does not disclose or suggest how the threshold voltages of NMOS and PMOS transistors can be reduced in a class AB transconductor circuit.

U.S. Pat. No. 6,456,157 B1 discloses a compensation circuit for regulating transistor threshold voltages in integrated circuits. The compensation circuit includes a transistor, a current source and a gate reference voltage supply. The transistor is biased to provide a well bias voltage, or back gate voltage, which is coupled to transistors on a common integrated circuit. More particularly the current source forces current into the drain of the transistor causing its back gate to be forward biased and adjusting the back gate bias voltage. This specification states that the compensation technique disclosed can be used to control the back gate voltage for NMOS target transistors (using a NMOS compensation circuit) and for PMOS target transistors (using a PMOS compensation circuit). However there is no provision for compensating NMOS and PMOS transistors simultaneously where one or other type of transistor has no well.

It is an object of the present invention to be able to compensate simultaneously NMOS and PMOS transistors used in a class AB transconductor circuit, where one or other type of transistor has no well.

According to one aspect of the present invention there is provided a class AB transconductor circuit comprising complementary PMOS and NMOS transistors having their source-drain paths connected in series between first and second voltage supply rails, an output terminal coupled to a junction of said series connected source-drain paths, and their gate electrodes coupled to an input terminal by way of respective first and second paths, wherein first and second bias voltage supply means are respectively provided in the first and second paths.

According to a second aspect of the present invention there is provided a balanced class AB transconductor circuit comprising first and second transconductor circuits made in accordance with the first aspect of the present invention, balanced inputs being applied to the respective input terminals and balanced outputs being derived from the respective output terminals.

According to a third aspect of the present invention there is provided an integrated circuit comprising a class AB transconductor circuit or balanced class AB transconductor circuit made in accordance with the first or second aspect of the present invention.

According to a fourth aspect of the present invention there is provided a transceiver comprising a class AB transconductor circuit made in accordance with the first or second aspect of the present invention.

The present invention will now be described, by way of example, with reference to the accompanying drawings, wherein:

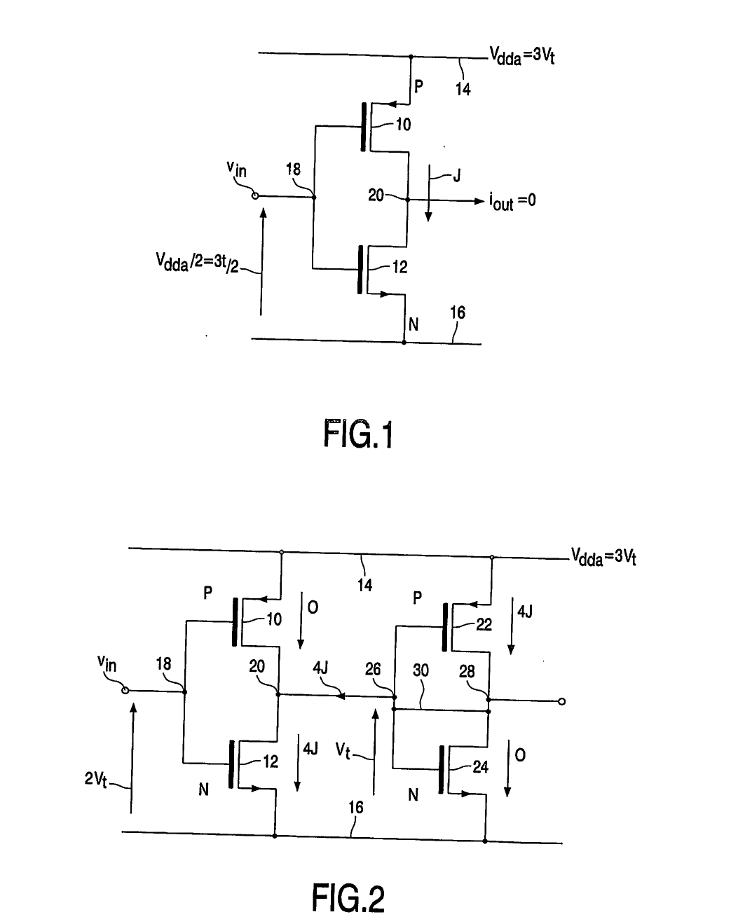

FIG. 1 is a circuit diagram of a class AB transconductor suitable for use in current CMOS technology,

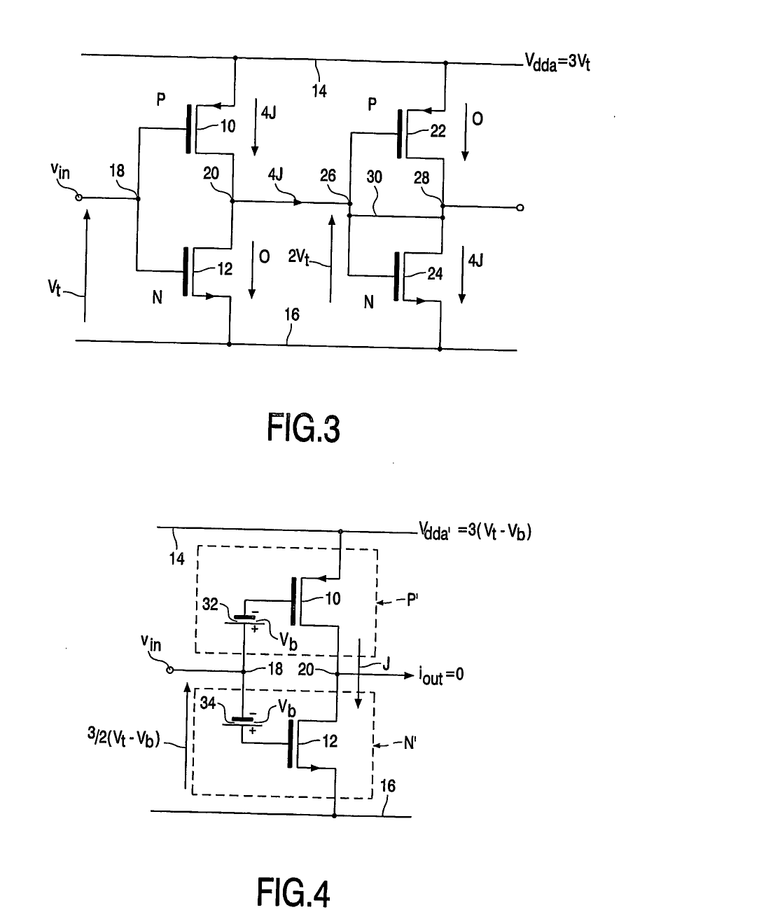

FIGS. 2 and 3 are circuit diagrams explaining the extreme conditions of the useful linear range of the transconductor shown in FIG. 1,

FIG. 4 is a conceptual circuit diagram of a class AB transconductor made in accordance with the present invention,

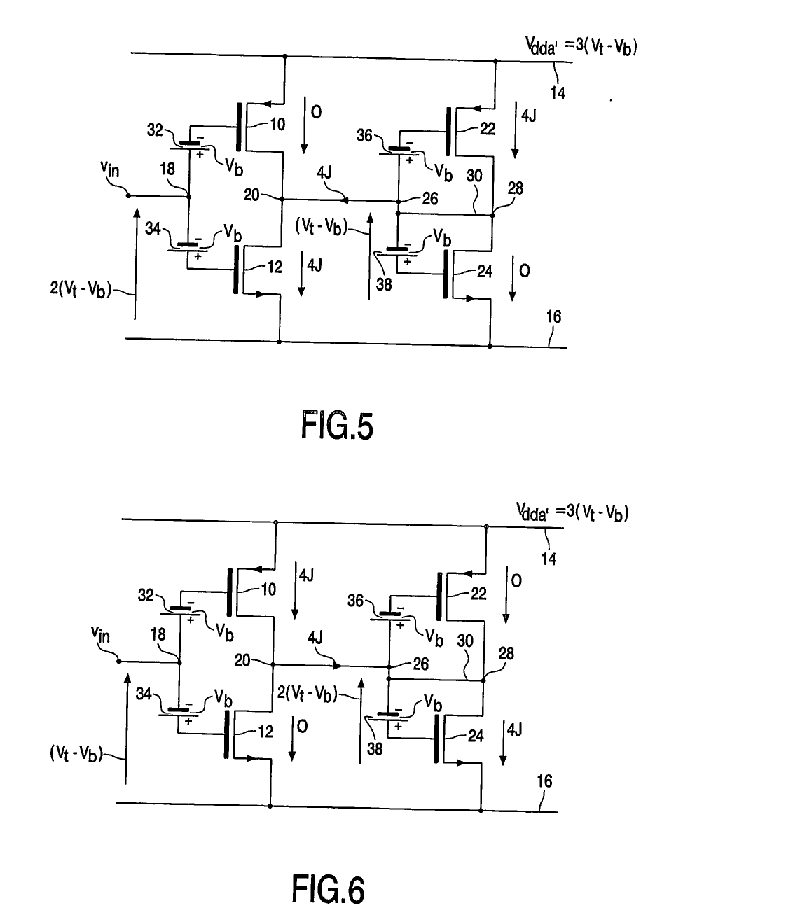

FIGS. 5 and 6 are conceptual circuit diagrams illustrating saturated operation of the class AB transconductor shown in FIG. 4 over the whole output current range of ±4J,

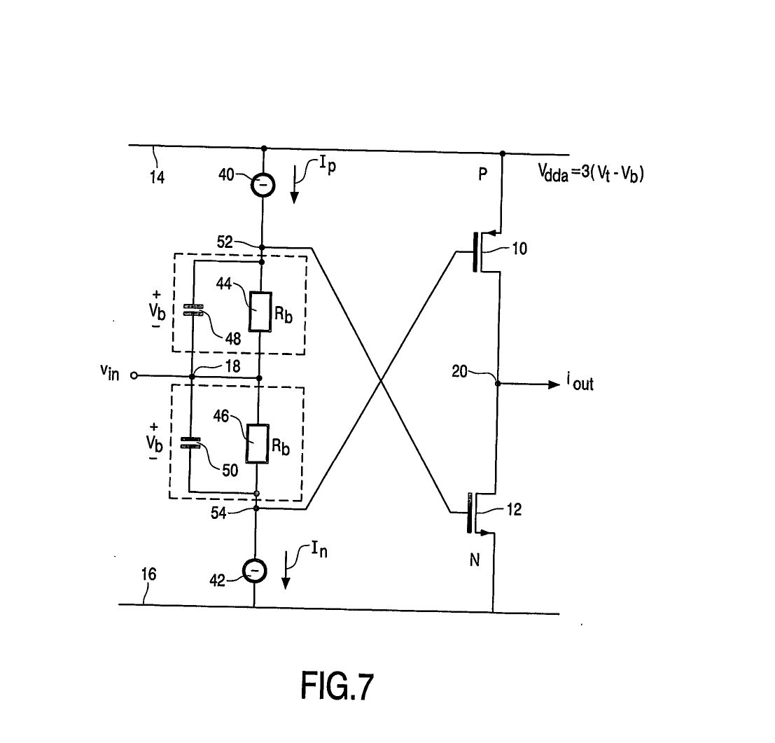

FIG. 7 is a circuit diagram of an embodiment of a single ended class AB transconductor made in accordance with the present invention,

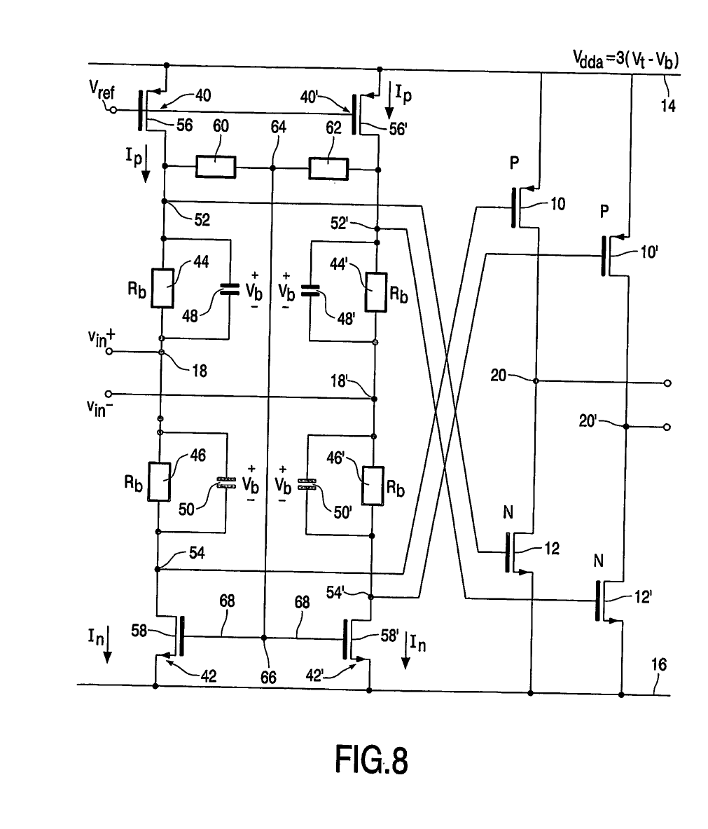

FIG. 8 is a circuit diagram of an embodiment of a balanced class AB transconductor made in accordance with the present invention,

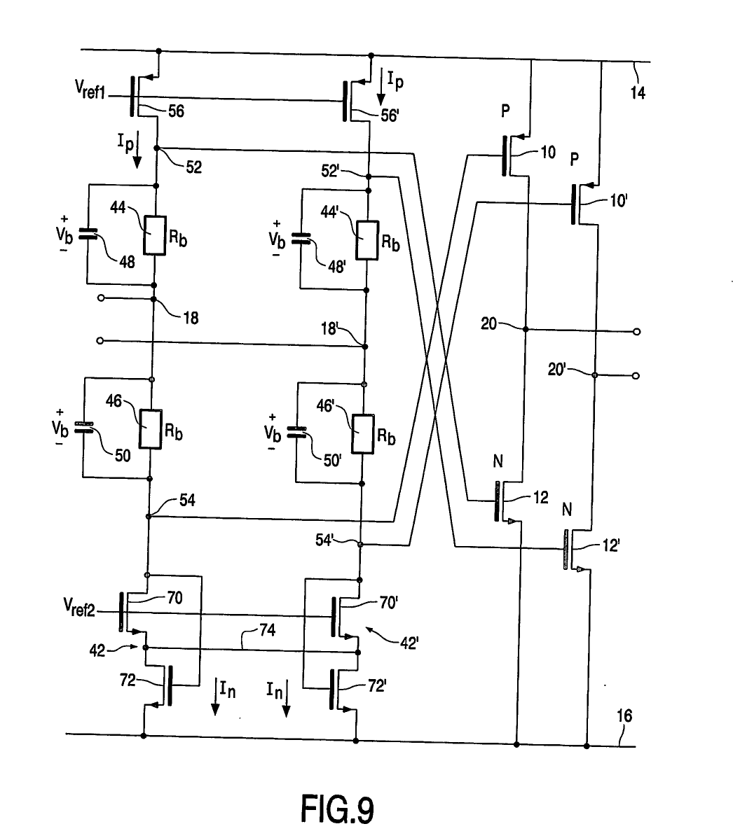

FIG. 9 is a circuit diagram of another embodiment of a balanced class AB transconductor made in accordance with the present invention, and

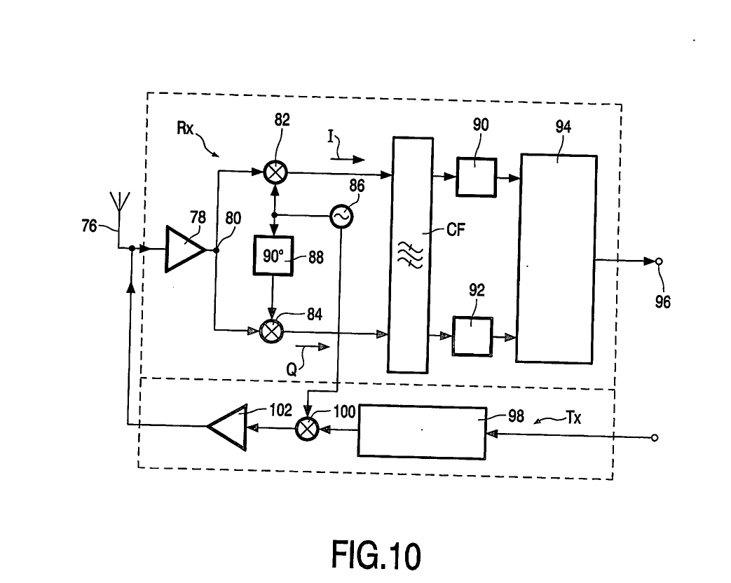

FIG. 10 is a block schematic diagram of a transceiver having a polyphase filter comprising balanced gyrators which include balanced class AB transconductors made in accordance with the present invention.

In the drawings the same reference numerals have been used to indicate corresponding features.

In order to illustrate the supply voltage versus threshold voltage problem in CMOS processes as they enter what is termed the deep sub-micron era a comparison is made between the supply and threshold voltages of typical currently available CMOS transistors and of CMOS transistors produced by an anticipated future process.

| | Process supply | Threshold voltage | Process |
|---|---|---|---|
| Technology (μm) | voltage V_{dd} (V) | Vₜ (V) | identification |
| 0.18 | 1.8 | 0.35 | Current |
| 0.05 | 0.6 | 0.20 | Future |

From the comparison it can be seen that the ratio V_{dd}/Vₜ for the current technology is of the order of 5, which is not unlike older processes having supply voltages of 5V and a V_{dd}/Vₜ ratio of more than 6, whereas for the anticipated future technology the ratio is 3. Since the threshold voltage is falling more slowly than the supply voltage it has been suggested that leakage problems in logic gates in future processes may force the use of even higher threshold voltages which will have an unfavourable effect on the V_{dd}/Vₜ ratio.

Referring to FIG. 1 the illustrated class AB transconductor suitable for use with current CMOS processing comprises a PMOS transistor 10 and a NMOS transistor 12 whose source-drain paths are connected in series between power supply rails 14, 16. The supply rail 14 is at a voltage V_{dda}. The gate electrodes of the transistors 10, 12 are connected to a junction 18 to which an input signal vᵢₙ is applied. An output signal Iₒᵤₜ is derived from a junction 20 of the drain electrodes of the transistors 10, 12.

For ease of the following explanation it will be assumed that the transistors 10, 12 have an ideal square-law saturated behaviour and identical parameters. Thus for a quiescent input voltage V_{dda}/2 producing equal currents J in the transistors 10, 12, a zero output current is obtained.

Referring to FIGS. 2 and 3, the class AB transconductor shown in FIG. 1 is terminated by another identical transconductor comprising a PMOS transistor 22 and a NMOS transistor 24 whose source-drain paths are connected in series. The gate electrodes of the transistors 22, 24 are connected to a junction 26 which is connected to the output junction 20 of the class AB transconductor, that is CMOS transistors 10,12. The drain electrodes of the transistors 22,24 are connected to a junction 28. A conductive link 30 interconnects the junctions 26 and 28 and thereby the drain and gate electrodes of the respective transistors 22, 24.

In FIG. 2 if the input voltage vᵢₙ is increased from the quiescent voltage V_{dda}/2 then eventually the current in the PMOS transistor 10 reaches zero as the current in the NMOS transistor reaches 4J. In FIG. 3 if the input voltage Vin is decreased from the quiescent voltage V_{dda}/2 then eventually the current in the NMOS transistor 12 reaches zero as the current in the PMOS transistor 10 reaches 4J. These two extreme conditions represent the useful linear range of the class AB transconductor, that is CMOS transistors 10, 12.

Considering FIGS. 1 to 3, it can be shown that if the quiescent gate overdrive voltage, V_{gt}=V_{gs}−Vₜ, is made equal to Vₜ/2, the analogue supply voltage is set to V_{dda}=3Vₜ and the quiescent input voltage is 3Vₜ/2, then the input voltages vᵢₙ producing these extreme conditions are 2Vₜ (FIG. 2) and Vₜ, (FIG. 3), and all the transistors stay saturated between these extremes. The choice represents the highest V_{gt} and the lowest V_{dda} that can simultaneously sustain saturated operation over the whole ±4J output signal range. If the V_{dda} rail 14 is generated from a regulator then the external supply V_{dd} must be greater than 3Vₜ (=4Vₜ). Use of the system V_{dd} with this optimum value gives the system with the lowest power consumption. A higher V_{dd} increases the power consumption directly whereas a lower V_{dd} is only possible with a lower V_{gt} which lowers the signal-to-noise (S/N) ratio and this can only be restored by increasing the power consumption. Referring to the above table it can be seen that the current technology is naturally near the optimum V_{da}/Vₜ ratio but in the anticipated future technology this ratio is expected to be below the optimum value for this ratio and unless some action is taken to try and achieve the optimum value a serious increase in power consumption could result if it is desired to maintain or improve upon the S/N ratio.

Referring to FIGS. 4 to 6, since the basic features of these circuits have already been described with reference to FIGS. 1 to 3, respectively, then in the interests of brevity FIGS. 4 to 6 will not be described in detail.

Referring to FIG. 4, the gate electrodes of the PMOS transistor 10 and the NMOS transistor 12 are connected by way of respective conceptual “batteries” 32, 34 to the input junction 18. The batteries 32, 34 have a voltage V_{b}. This effectively creates a transconductor with a pair of composite transistors P′ and N′, as shown in broken lines, with threshold voltages Vₜ′=Vₜ−V_{b}. If the circuit is operated from a supply voltage of V′_{dda}=3V′ₜ=3(Vₜ−V_{b}) and set V′_{gt}=V′ₜ/2=(Vₜ−V_{b})/2. In FIG. 4 the quiescent input voltage is 3/2(Vₜ−V_{b}) and the output current is zero.

FIGS. 5 and 6 illustrate the extreme operating conditions for saturated operation over the whole ±4J output current range. In the case of the transconductor consisting of the CMOS transistors 22, 24 conceptual batteries 36, 38 are coupled respectively between the gate electrodes of the transistors 22 and 24 and the junction 26. Thus in FIG. 5, the junctions 18 and 26 are respectively at voltages 2(Vₜ−V_{b}) and (Vₜ−V_{b}) and the current in the PMOS transistor 10 is zero whereas the current in the NMOS transistor 12 is 4J. The situation is the reverse in FIG. 6.

The “battery” voltage V_{b} may be designed to give the condition for minimum power consumption despite a non-optimum V_{dd}/Vₜ ratio, namely V_{dd}>3Vₜ(≈4 Vₜ).

FIG. 7 illustrates an implementation of a single-ended class AB transconductor circuit made in accordance with the present invention. Compared to the conceptual transconductor circuit shown in FIG. 4, the “batteries” are created by voltage drop of equal current Iₚ=Iₙ from respective current sources 40, 42 flowing in resistors 44, 46 having a value R_{b}. The resistors are decoupled by capacitors 48, 50. The gate electrodes of the transistors 12, 10 are connected to nodes 52, 54 located respectively at the junctions of the current sources 40, 42, and the resistors 44, 46. The gate voltages at the nodes 52, 54 are vᵢₙ+V_{b} and vᵢₙ−V_{b}, as before.

FIG. 8 illustrates an embodiment of a balanced arrangement of the class AB transconductor circuit shown in FIG. 7. Apart from the implementation of a common mode feedback circuit, the balanced arrangement is essentially two parallel single ended arrangements as shown in FIG. 7. Accordingly those parts of the duplicate transconductor (based on transistors 10′ and 12′) which correspond to the original transconductor (based on CMOS transistors 10, 12) have been referenced with primed corresponding reference numerals. Also in the interests of brevity only those parts of the balanced arrangement not previously described will be described.

The current sources 40, 40′ respectively comprise PMOS transistors 56, 56′ whose source-drain paths are connected between the voltage supply line 14 and the resistor 44, 44′ and whose gate electrodes are biased by a reference voltage V_{ref}. The current sources 42, 42′ respectively comprise NMOS transistors 58, 58′ whose drain-source paths are connected between the resistor 46, 46′ and the voltage supply line 16. The gate electrodes are biased by a common-mode feedback circuit comprising equal value resistors 60, 62 connected in series between the drain electrodes of the PMOS transistors 56, 56′. A junction 64 of the resistors 60, 62 is connected to a node 66 in a conductive link 68 between the gate electrodes of the transistors 58, 58′. The common feedback path produces the condition Iₚ=Iₙ, sets the input quiescent voltages and creates the required set of “batteries”.

More particularly the common mode feedback works by the PMOS transistors 10, 10′ creating bias currents Ip which flow into the nodes 52, 52′. The transistors 12, 12′ create bias currents Iₙ which flow into nodes 52, 52′ by way of the nodes 54, 54′. If Iₙ>Iₚ then the nodes 52, 52′ and 66 fall until Iₙ=Iₚ. Conversely, if Iₙ<Iₚ then the nodes 52, 52′ and 66 rise until Iₙ=Iₚ, Consequently the common-mode feedback circuit is stable with Iₙ=Iₚ. This is not disturbed by difference mode input voltages as these do not disturb the voltage at the node 66. Under quiescent conditions, and with all the transistors designed with equal gate overdrive voltages V_{gt}=(Vₜ−V_{b})/2, then the voltages at the nodes 52, 52′ are V_{gs 12,12′}=Vₜ+V_{gt}=(3Vₜ−V_{b})/2, and the voltages at the inputs are V_{Q}=V_{gs 12,12′}−V_{b}=(3Vₜ−V_{b})/2=V_{dda}/2. So the common-mode feedback circuit creates a mid-rail quiescent input voltage. Under signal conditions with a differential input voltage vᵢₙ, the input nodes are at νᵢₙ⁺=V_{Q}+νᵢₙ/2 and νᵢₙ⁻=V_{Q}−νᵢₙ/2, and the gate voltages at the nodes 52, 54 and the nodes 54′ and 52′ are νᵢₙ⁺−V_{b},νᵢₙ⁺+V_{b} and νᵢₙ⁻V_{b},νᵢₙ⁻+V_{b}, respectively.

It is desirable that the resistors 60, 62 should have a value R_{cm} such that R_{cm}>>1/Gₘ to avoid significant loading of the input nodes.

FIG. 9 illustrates another embodiment of a class AB transconductor circuit made in accordance with the present invention. The main difference between the embodiments shown in FIGS. 8 and 9 is in the implementation of the common mode feedback circuit. Accordingly in the interests of brevity a detailed circuit description will not be provided.

Instead of the common mode feedback arrangement shown in FIG. 8 in which the resistors 60, 62 are connected in series between the drain electrodes of the PMOS transistors 56, 56′ and a connection from a junction of these resistors is connected to the gate electrodes of the NMOS transistors constituting the current sources 42,42′, there are no similar connections to the drain electrodes of the PMOS transistors 56, 56′ but instead the current sources 42, 42′ comprise respectively a NMOS transistor 70, 70′ having its source electrode connected to the drain electrode of a NMOS transistor 72, 72′ and its drain electrode coupled to the resistor 46, 46′. The source electrodes of the NMOS transistors 72, 72′ are connected to the power supply rail 16. Gate electrodes of the NMOS transistors 72, 72′ are connected respectively to the drain electrodes of the NMOS transistors 70, 70′. Junctions of the source electrodes of the NMOS transistors 70, 70′ and the drain electrodes of the NMOS transistors 72, 72′ are interconnected by a conductive link 74. The gate electrodes of the PMOS transistors 56, 56′ are biased by a first reference voltage source V_{ref1} and the gate electrodes of the NMOS transistors 70, 70′ are biased by a second reference voltage source V_{ref2}.

In operation the NMOS transistors 72, 72′ are triode operated transistors which means that their resistances can be altered by varying the bias voltages on their gate electrodes. If, for example, the voltage at the junction 18′ is much higher than the voltage at the junction 18, the gate voltage on the NMOS transistor 72′ increases causing the resistance to decrease and the drain-source current to increase until Iₚ=Iₙ.

In the differential drive mode, the resistances of the transistors 72, 72′ are short circuited by the conductive link 74 causing the sum of the differential currents to be zero. The common mode operation is oblivious to the input signals.

The balanced class AB transconductor circuits are frequently used in gyrator filters, which generally exclude op-amps, employed as IF filters and channel filters in low voltage transceivers. FIG. 10 illustrates an embodiment of a transceiver in which a polyphase channel filter CF in the receiver section Rx comprises two fifth order bandpass filters, one for each of the quadrature related phases.

An antenna 76 is coupled to a low noise amplifier (LNA) 78 in the receiver section Rx. An output of the LNA 78 is coupled by way of a signal divider 80 to first inputs of quadrature related mixers 82, 84. A local oscillator signal generated by a signal generator 86 is applied to a second input of the mixer 82 and, by way of a ninety degree phase shifter 88, to a second input of the mixer 84. Quadrature related outputs 1, Q, respectively, from the mixers 82, 84 are applied to the polyphase channel filter CF which passes the wanted quadrature related signals to respective analogue-to-digital converters 90, 92. The digital outputs from the A-to-D converters 90, 92 are applied to a digital demodulator 94 which provides an output signal on a terminal 96.

The transmitter Tx comprises a digital modulator 98 which includes a digital-to-analogue converter (not shown) providing an analogue signal to a mixer 100 for frequency up-conversion to the required transmission frequency. A power amplifier 102 amplifies the frequency up-converted signal and supplies it to the antenna 76.

The transceiver including the channel filter CF may be fabricated as an integrated circuit using known low voltage CMOS processes.

In the present specification and claims the word “a” or “an” preceding an element does not exclude the presence of a plurality of such elements. Further, the word “comprising” does not exclude the presence of other elements or steps than those listed.

From reading the present disclosure, other modifications will be apparent to persons skilled in the art. Such modifications may involve other features which are already known in the design, manufacture and use of class AB transconductor circuits and component parts therefor and which may be used instead of or in addition to features already described herein. Although claims have been formulated in this application to particular combinations of features, it should be understood that the scope of the disclosure of the present application also includes any novel feature or any novel combination of features disclosed herein either explicitly or implicitly or any generalisation thereof, whether or not it relates to the same invention as presently claimed in any claim and whether or not it mitigates any or all of the same technical problems as does the present invention. The applicants hereby give notice that new claims may be formulated to such features and/or combinations of such features during the prosecution of the present application or of any further application derived therefrom.

1. A class AB transconductor circuit comprising complementary PMOS and NMOS transistors having their source-drain paths connected in series between first and second voltage supply rails, an output terminal coupled to a junction of said series connected source-drain paths, and their gate electrodes coupled to an input terminal by way of respective first and second paths, wherein first and second bias voltage supply means are respectively provided in the first and second paths.

2. A transconductor circuit as claimed in claim 1, characterised in that the first and second bias voltage supply means comprise first and second series connected resistors coupled between a first current source connected to the first voltage supply rail and a second current source connected to the second voltage supply rail, and in that the input terminal is connected to a common junction (18) of the first and second series connected resistors.

3. A transconductor circuit as claimed in claim 2, characterised in that the first and second resistors are decoupled by respective capacitances.

4. A transconductor circuit as claimed in claim 2, characterised in that the gate electrode of the PMOS transistor is coupled to a junction of the second resistor and the second current source and in that the gate electrode of the NMOS transistor is coupled to a junction of the first resistor and the first current source.

5. A balanced class AB transconductor circuit comprising first and second transconductor circuits as claimed claim 1, balanced inputs being applied to the respective input terminals and balanced outputs being derived from the respective output terminals.

6. A balanced class AB transconductor circuit comprising first and second transconductor circuits as claimed in claim 4, characterised in that balanced inputs are applied to the respective input terminals, in that balanced outputs are derived from the respective output terminals, in that the first current sources of each of the first and second transconductor circuits comprise externally biased PMOS transistors, in that the second current sources of each of the first and second transconductor circuits comprise NMOS transistors, and in that a common mode feedback circuit is provided, the common mode feedback circuit comprising first and second substantially equal value resistors coupled in series between drain electrodes of the externally biased PMOS transistors and a connection from a common junction of the first and second substantially equal valued resistors to the gate electrodes of the NMOS transistors.

7. A balanced class AB transconductor circuit comprising first and second transconductor circuits as claimed in claim 4, characterised in that balanced inputs are applied to the respective input terminals, in that balanced outputs are derived from the respective output terminals, in that the first current sources of each of the first and second transconductor circuits comprise externally biased PMOS transistors, in that the second current sources of each of the first and second transconductor circuits comprise externally biased NMOS transistors, and in that common mode feedback circuit means are provided, the common mode feedback circuit means comprising for each of the first and second transconductor circuits a triode operated NMOS transistor having its drain-source path coupled between the source electrode of the externally biased NMOS transistor and the second voltage supply rail and its gate electrode connected to the drain electrode of the externally biased NMOS transistor; the source electrodes of the externally biased NMOS transistors being interconnected.

8. An integrated circuit comprising a balanced class AB transconductor circuit as claimed in claim 5.

9. An integrated transceiver comprising a class AB transconductor circuit as claimed in claim 1.
